(19) United States
(12) Patent Application Publication
(10) Pub. No.: US 2006/0289893 A1
(43) Pub. Date: Dec. 28, 2006

(54) Display device and driving apparatus having reduced pixel electrode discharge time upon power cut-off

(75) Inventors: Yong-Soon Lee, Chungcheongnam-do (KR); Seung-Hwan Moon, Gyeonggi-do (KR); Haeng-Won Park, Gyeonggi-do (KR); Nam-Soo Kang, Gyeonggi-do (KR)

Correspondence Address: Att: Patent Group;Kieun "Jenny" Sung, DLA Piper Rudnick Gray Cary US LLP, 2000 University Avenue, East Palo Alto, CA, 94303, US

(73) Assignee: Samsung Electronics Co., Ltd.

(21) Appl. No.: 11/476,241

(22) Filed: Jun. 27, 2006

(30) Foreign Application Priority Data
Jun. 27, 2005 (KR) 10-2005-0055734

(51) Int. Cl. H01L 29/74

(52) U.S. Cl. 257/147

(57) ABSTRACT

A driving apparatus of a display device including a plurality of switching elements and a plurality of pixel electrodes connected to the switching elements is provided, in which the apparatus includes a gate-off voltage generator for generating a gate-off voltage and a gate driver for outputting the gate-off voltage from the gate-off voltage generator to the switching elements, wherein the gate-off voltage generator increases the gate-off voltage to a predetermined voltage when a power supply voltage applied to the display device is cut off.

### RELATED APPLICATION

The present application claims priority from Korean Patent Application No. 2005-0055734 filed on Jun. 27, 2005, the disclosure of which is hereby incorporated herein by reference in its entirety.

### BACKGROUND OF THE INVENTION

(a) Field of the Invention

The present invention relates to a display device and a driving apparatus thereof.

(b) Description of Related Art

A liquid crystal display (LCD) is a type of flat panel display that has been widely used, and it includes two panels provided with field-generating electrodes such as pixel electrodes and a common electrode. A liquid crystal (LC) layer having dielectric anisotropy is interposed between the panels, and images are controlled by a gate driver for generating gate signals (e.g., a gate-on voltage and a gate-off voltage) and a data driver for outputting data signals.

The pixel electrodes are arranged in a matrix and connected to switching elements such as thin film transistors (TFTs) which are turned on or turned off by the gate-on voltage or the gate-off voltage. The gate driver applies the gate-on voltage to the switching elements connected to the pixel electrodes in rows and sequentially turns on the switching elements. The pixel electrodes are supplied with voltages of the data signals through the turned-on switching elements. The common electrode covers an entire surface of one of the two panels and is supplied with a common voltage. The pixel electrode, the common electrode, and the LC layer form an LC capacitor, which is a basic element of a pixel along with a switching element.

The LCD applies voltages to the field generating electrodes to generate an electric field in the LC layer, and the strength of the electric field can be controlled by adjusting the voltage across the LC capacitor. Since the electric field determines the orientations of LC molecules and the molecular orientations determine the transmittance of light passing through the LC layer, light transmittance is adjusted by controlling the applied voltages, thereby obtaining the desired images.

When a power supply voltage applied to the LCD is cut off using a switch, the voltage (pixel electrode voltage) applied to the pixel electrode is not rapidly discharged. This slow discharge causes image deterioration. In response to the turning-off of the switch, the displayed image has to disappear from the screen. However, due to the slow discharge of the pixel electrode voltage, the image lingers on the screen until the pixel electrode voltage is totally discharged through a turned-on switching element.

The discharging speed of the pixel electrode voltage is at least partly dependent on the gate-off voltage. That is, when a gate-off voltage of about −10 V to −15 V is discharged to a ground voltage such as about 0 V, the pixel electrode voltage is discharged via the switching element and the data driver based on the variation of the switching element due to the discharging of the gate-off voltage.

Reducing the pixel electrode discharge time would reduce image deterioration upon turning off an LCD display device.

### SUMMARY OF THE INVENTION

A motivation of the present invention is to solve the above-mentioned problems.

In one aspect of the preset invention, a driving apparatus of a display device including a plurality of switching elements and a plurality of pixel electrodes connected to the switching elements is provided. The apparatus includes a gate-off voltage generator for generating a gate-off voltage and a gate driver for outputting the gate-off voltage from the gate-off voltage generator to the switching elements. The gate-off voltage generator increases the gate-off voltage to a predetermined voltage when a power supply voltage applied to the display device is cut off.

The gate-off voltage generator may include a charge pumping unit for increasing an input voltage from the outside in a preselected (−) direction by a predetermine magnitude to generate the gate-off voltage, and an offset voltage generator for generating an offset voltage and adding the offset voltage to the discharge gate-off voltage to apply it to the switching element when the gate-off voltage from the charge pumping unit is discharged. The gate-off voltage generator may also include at least one diode unit connected in a reverse direction between an output terminal of the charge pumping unit and the gate driver, and a capacitor connected in parallel with the diode unit.

The offset voltage may be controlled by the diode unit, and the diode unit may include three diodes connected in series.

The gate-off voltage generator may further include a discharging unit for providing a discharge path for the gate-off voltage. The discharging unit may include a resistor and a capacitor connected in parallel with the charge pumping unit.

The discharging unit may include a first capacitor connected in parallel to the charge pumping unit, a transistor having a collector terminal connected to the charge pumping unit and an emitter terminal grounded, a resistor connected to the emitter terminal and a base terminal of the transistor, and a second capacitor connected to the resistor, and a supply voltage connected to the second capacitor. The transistor may be pnp-type transistor.

The power supply voltage may be received from an external device, and a magnitude of the power supply voltage may be changed to the ground voltage when the power supply voltage e is cut off.

The predetermine voltage may be the ground voltage.

In another aspect of the present invention, a display device includes a plurality of switching elements, a plurality of pixel electrodes, a plurality of gate lines connected to the switching elements and transmitting a gate-off voltage to the switching elements, a gate-off voltage generator for generating the gate-off voltage, and a gate driver for outputting the gate-off voltage from the gate-off voltage generator to the switching elements, wherein the gate-off voltage generator increases the gate-off voltage up a predetermined voltage when a power supply voltage applied to the display device is cut off.

The gate-off voltage generator may include a charge pumping unit for increasing an input voltage from the outside in a preselected (−) direction by a predetermine magnitude to generate the gate-off voltage, an offset voltage generator for generating an offset voltage and adding the offset voltage to the discharge gate-off voltage to apply it to the switching element when the gate-off voltage from the charge pumping unit is discharged, at least one diode unit connected in a reverse direction between an output terminal of the charge pumping unit and the gate driver, and a capacitor connected in parallel to the diode unit. Alternately, the diode unit may include three diodes connected in series.

The gate-off voltage generator may further include a discharging unit for supplying a discharge path for the gate-off voltage. The discharging unit may include a resistor and a capacitor connected in parallel with the charge pumping unit.

The discharging unit may include a first capacitor connected in parallel with the charge pumping unit, a transistor having a collector terminal connected to the charge pumping unit and an emitter terminal grounded, a resistor connected to the emitter terminal and a base terminal of the transistor, and a second capacitor connected to the resistor, and a supply voltage connected to the second capacitor. The transistor may be pnp-type junction transistor.

The power supply voltage may be externally applied, and a magnitude of the power supply voltage may be changed to the ground voltage when the power supply voltage is cut off.

The predetermined voltage may be ground voltage.

### BRIEF DESCRIPTION OF THE DRAWINGS

The present invention will become more apparent by describing preferred embodiments thereof in detail with reference to the accompanying drawings in which:

FIG. 1 is a block diagram of an LCD according to an embodiment of the present invention;

FIG. 2 is an equivalent circuit diagram of a pixel of an LCD according to an embodiment of the present invention;

FIG. 3 is a circuit diagram of a gate-off voltage generator according to a first embodiment of the present invention;

FIG. 4 is an equivalent circuit diagram of the gate-off voltage generator shown in FIG. 3, with a gate driver and a data driver connected to a switching element of a pixel, when a power supply voltage of an LCD according to an embodiment of the present invention is cut off;

FIG. 5 is a graph showing a current flowing between an output terminal and an input terminal of a switching element with respect to a voltage applied between a control terminal and the output terminal of the switching element of an a-Si thin film transistor;

FIG. 6 is a circuit diagram of a gate-off voltage generator according to a second embodiment of the present invention;

FIG. 7 is an equivalent circuit diagram of the gate-off voltage generator shown in FIG. 6, with a gate driver and a data driver connected to a switching element of a pixel, when a power supply voltage of an LCD according to an embodiment of the present invention is cut off;

FIG. 8 is a graph showing variations of pixel electrode voltages with respect to control voltages, when a power supply voltage of an LCD according to an embodiment of the present invention is cut off;

FIG. 9 is a circuit diagram of a gate-off voltage generator according to a third embodiment of the present invention; and

FIG. 10 is a graph showing variations of control voltages applied to a control terminal of a switching element connected to a pixel electrode and pixel electrode voltages, when a discharging portion shown in FIG. 9 is adopted.

### DETAILED DESCRIPTION OF EMBODIMENTS

The present invention will be described more fully hereinafter with reference to the accompanying drawings, in which preferred embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, film, region, substrate or panel is referred to as being “on” another element, it can be directly on the other element or intervening elements may also be present.

LCDs and driving apparatuses thereof according to an embodiment of the present invention will now be described with reference to the drawings.

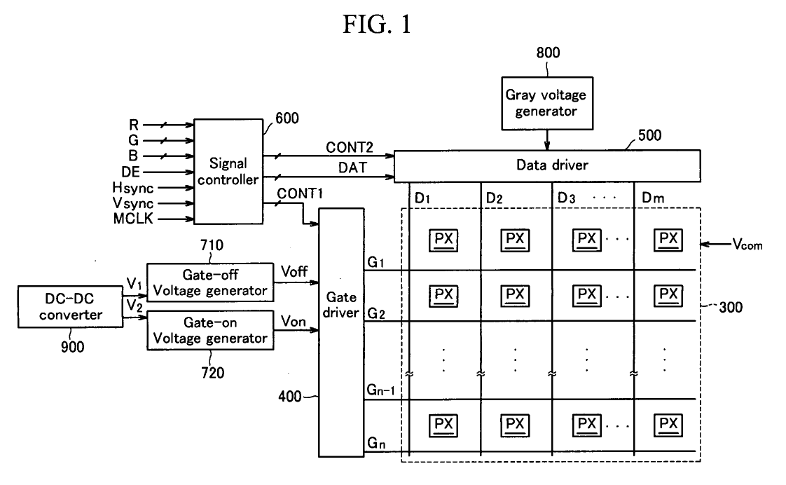

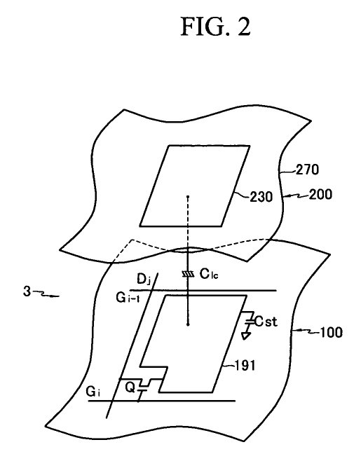

FIG. 1 is a block diagram of an LCD according to an embodiment of the present invention, and FIG. 2 is an equivalent circuit diagram of a pixel of an LCD according to an embodiment of the present invention.

Referring to FIG. 1, an LCD according to an embodiment of the present invention includes an LC panel assembly 300, a gate driver 400 and a data driver 500 connected thereto, a DC-DC converter 900, a gate-off voltage generator 710 connected to the DC-DC converter 900 and the gate driver 400, a gate-on voltage generator 720 connected to the DC-DC converter 900 and the gate driver 400, a gray voltage generator 800 connected to the data driver 500, and a signal controller 600 controlling the above-described elements.

The LC panel assembly 300, in a structural view shown in FIG. 2, includes a lower panel 100, an upper panel 200, and an LC layer 3 interposed therebetween, and it includes a plurality of display signal lines G1-Gn and D1-Dm and a plurality of pixels PX connected thereto and arranged substantially in a matrix format in a circuital view shown in FIGS. 1 and 2.

The display signal lines G1-Gn and D1-Dm are provided on the lower panel 100 and include a plurality of gate lines G1-Gn for transmitting gate signals (called scanning signals) and a plurality of data lines D1-Dm for transmitting data signals. The gate lines G1-Gn extend substantially in a first direction and are substantially parallel to each other, while the data lines D1-Dm extend substantially in a second direction that is perpendicular to the first direction and are substantially parallel to each other.

Each pixel PX, for example a pixel PX connected to the i_th gate line Gᵢ(i=1, 2, . . . , m) and the j_th data line Dⱼ (j=1, 2, . . . , m), includes a switching element Q connected to the signal lines Gᵢ and Dⱼ, and an LC capacitor Clc and a storage capacitor Cst that are connected to the switching element Q. The storage capacitor Cst may be omitted if it is unnecessary.

The switching element Q such as a TFT is provided on the lower panel 100 and has three terminals: a control terminal connected to the gate lines Gᵢ; an input terminal connected to the data lines Dⱼ; and an output terminal connected to the LC capacitor Clc and the storage capacitor Cst.

The LC capacitor Clc includes a pixel electrode 191 provided on the lower panel 100 and a common electrode 270 provided on the upper panel 200, as two terminals. The LC layer 3 disposed between the two electrodes 191 and 270 functions as a dielectric of the LC capacitor Clc. The pixel electrode 191 is connected to the switching element Q, and the common electrode 270 is supplied with a common voltage Vcom and covers an entire surface of the upper panel 200. Unlike in FIG. 2, the common electrode 270 may be provided on the lower panel 100, and both electrodes 191 and 270 may be shaped into bars or stripes.

The storage capacitor Cst is an auxiliary capacitor for the LC capacitor Clc. The storage capacitor Cst includes the pixel electrode 191 and a separate signal line (not shown), which is provided on the lower panel 100. The signal line overlaps the pixel electrode 191 via an insulator, and is supplied with a predetermined voltage such as the common voltage Vcom. Alternatively, the storage capacitor Cst includes the pixel electrode 191 and an adjacent gate line called a previous gate line, which overlaps the pixel electrode 191 via an insulator.

For color display, each pixel uniquely represents one of the primary colors (i.e., spatial division) or each pixel sequentially represents the primary colors in turn (i.e., temporal division), such that a spatial or temporal sum of the primary colors is recognized as a desired color. An example of a set of the primary colors includes red, green, and blue. FIG. 2 shows an example of the spatial division in which each pixel includes a color filter 230 representing one of the primary colors in an area of the upper panel 200 facing the pixel electrode 191. Alternatively, the color filter 230 is provided on or under the pixel electrode 191 on the lower panel 100.

A pair of polarizers (not shown) for polarizing light are attached on the outer surfaces of the panels 100 and 200 of the panel assembly 300.

The gray voltage generator 800 generates two sets of a plurality of gray voltages (or two sets of a plurality of reference gray voltages) related to the transmittance of the pixels. The gray voltages in one set have a positive polarity with respect to the common voltage Vcom, while those in the other set have a negative polarity with respect to the common voltage Vcom.

The DC-DC converter 900 converts a DC voltage from the outside (not shown) into a plurality of DC voltages V1 and V2 of desired magnitudes. The voltage V1 is a ground voltage of about 0V and the voltage V2 has a magnitude of about +8V.

The gate-off voltage generator 710 converts the DC voltage V1 from the DC-DC converter 900 into a voltage of a predetermined magnitude, for example, about −10V, to output as a gate-off voltage Voff.

The gate-on voltage generator 720 converts the DC voltage V2 from the DC-DC converter 900 into a voltage of a predetermined magnitude, for example, about +20V, to output as a gate-on voltage Von.

The gate driver 400 is connected to the gate lines G1-Gn of the panel assembly 300 and synthesizes the gate-off voltage Voff and the gate-on voltage Von to generate gate signals for application to the gate lines G1-Gn. The gate-off voltage Voff is generated in the gate-off voltage generator 710 and the gate-on voltage Von is generated in the gate-on voltage generator 720.

The data driver 500 is connected to the data lines D1-Dm of the panel assembly 300 and applies data voltages selected from the gray voltages to the data lines D1-Dm. The gray voltages are supplied by the gray voltage generator 800. When the gray voltage generator 800 supplies reference gray voltages of a predetermined number such that the reference gray voltages do not correspond to all gray levels (e.g., the predetermined number is less than the total number of gray levels), the data driver 500 divides the reference gray voltages to generate the gray voltages corresponding to all gray levels and selects data voltages from the generated gray voltages.

The signal controller 600 controls the drivers 400 and 500.

The respective driving devices 400, 500, 600, 710, 720, 800, and 900 may be implemented as an integrated circuit (IC) chip mounted on the panel assembly 300, mounted on a flexible printed circuit (FPC) film as a tape carrier package (TCP) type and attached to the LC panel assembly 300, or mounted on a separate printed circuit board (PCB). Alternately, the driving devices 400, 500, 600, 710, 720, 800, and 900 may be integrated into the panel assembly 300 along with the display signal lines G1-Gn and D1-Dm and the TFT switching elements Q. In addition, the driving devices 400, 500, 600, 710, 720, 800, and 900 may be implemented as an IC chip, and at least one of them or at least a circuit element included in them may be implemented out of the IC chip.

Now, the operation of the LCD will be described in detail.

The signal controller 600 is supplied with RGB image signals R, G, and B and input control signals controlling the display of the RGB image signals R, G, and B from an external graphic controller (not shown). Examples of the input control signals are a vertical synchronization signal Vsync, a horizontal synchronization signal Hsync, a main clock signal MCLK, and a data enable signal DE.

After generating gate control signals CONT1 and data control signals CONT2 and processing the image signals R, G, and B to be suitable for the operation of the panel assembly 300 on the basis of the input control signals, the signal controller 600 provides the gate control signals CONT1 for the gate driver 400, and the processed image signals DAT and the data control signals CONT2 for the data driver 500.

The gate control signals CONT1 include a scanning start signal STV for instructing to start scanning, and at least a clock signal for controlling the output time of the gate-on voltage Von. The gate control signals CONT1 may further include an output enable signal OE for defining the duration of the gate-on voltage Von.

The data control signals CONT2 include a horizontal synchronization start signal STH for informing the start of data transmission for a group of pixels, LOAD for instructing to apply the data voltages to the data lines D1-Dm, and a data clock signal HCLK. The data control signal CONT2 may further include an inversion control signal RVS for reversing the polarity of the data voltages (with respect to the common voltage Vcom).

In response to the data control signals CONT2 from the signal controller 600, the data driver 500 receives a packet of the image data DAT for the group of pixels from the signal controller 600, converts the image data DAT into analog data voltages selected from the gray voltages supplied from the gray voltage generator 800, and applies the data voltages to the data lines D1-Dm.

The gate-off voltage generator 710 converts the voltage V1 from the DC-DC converter 900 into a DC voltage of about −7V, to output as the gate-off voltage Voff. In addition, the gate-off voltage 710 discharges pixel electrode voltages applied to the pixel electrodes 191 through the switching elements Q when a power supply voltage supplied for driving the LCD is cut off. The gate-off voltage generator 710 will be described in detail below.

The gate-on voltage generator 720 boosts the voltage V2 from the DC-DC converter 900 into a DC voltage of about +20V using a charge pumping unit, to output as the gate-on voltage Von.

The gate driver 400 applies the gate-on voltage Von to the gate line G1-Gn in response to the gate control signals CONT1 from the signal controller 600, thereby turning on the switching elements Q connected thereto. The data voltages applied to the data lines D1-Dm are supplied to the pixels through the activated switching elements Q.

The difference between the data voltage and the common voltage Vcom is represented as a voltage across the LC capacitor Clc, which is referred to as a pixel voltage. The LC molecules in the LC capacitor Clc have orientations depending on the magnitude of the pixel voltage, and the molecular orientations determine the polarization of light passing through the LC layer 3. The polarizer(s) converts the light polarization into light transmittance.

By repeating this procedure by a unit of the horizontal period (which is denoted by “1H ” and is equal to one period of the horizontal synchronization signal Hsync and the data enable signal DE), all gate lines G1-Gn are sequentially supplied with the gate-on voltage Von during a frame, thereby applying the data voltages to all pixels. When the next frame starts after finishing one frame, the inversion control signal RVS applied to the data driver 500 is controlled such that the polarity of the data voltages is reversed (which is referred to as “frame inversion”). The inversion control signal RVS may also be controlled such that the polarity of the data voltages flowing in a data line in one frame are reversed (for example line inversion and dot inversion), or the polarity of the data voltages in one packet are reversed (for example column inversion and dot inversion).

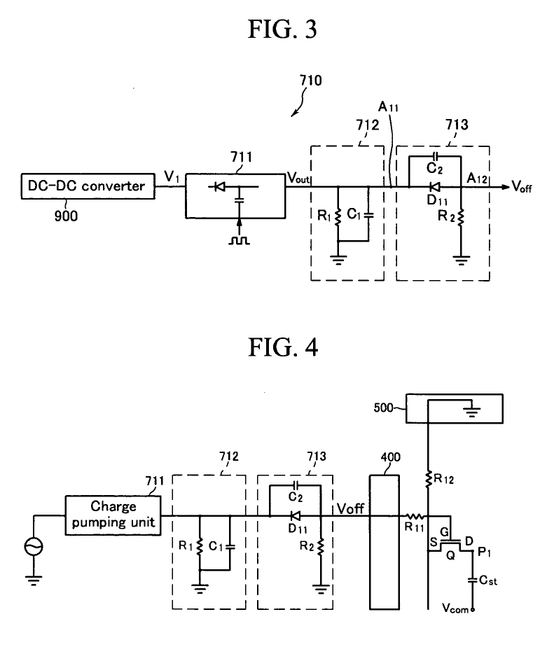

Now, the gate-off voltage generator 710 according to a first embodiment of the present invention will be described with reference to FIGS. 3 and 4.

FIG. 3 is a circuit diagram of a gate-off voltage generator according to a first embodiment of the present invention, and FIG. 4 is an equivalent circuit diagram of the gate-off voltage generator shown in FIG. 3. A gate driver and a data driver are connected to a switching element of a pixel, and the power supply is cut off from the LCD.

Referring to FIG. 3, the gate-off voltage generator 710 includes a charge pumping unit 711, a discharging unit 712, and an offset voltage generator 713 connected to the discharging unit 712.

The charge pumping unit 711 includes diodes (not shown) and capacitors (not shown) connected in parallel to each other, and receives an external pulse signal. The diodes are connected serially in a reverse direction from the DC-DC converter 900.

The discharging unit 712 includes a resistor R1 and a capacitor C1 connected in parallel.

The offset voltage generator 713 includes a diode D11 connected in the reverse direction from the discharging unit 712 and outputting the gate-off voltage Voff through an anode terminal thereof, a resistor R2 connected between the anode terminal of the diode D11 and a ground, and a capacitor C2 connected between both terminals of the diode D11.

Operations of the gate-off voltage generator 710 will now be described.

First, an operation of the gate-off voltage generator 710 will be described when the LCD is normally operated by supplying the power supply voltage thereto.

When the DC voltage V1 of about 0V is applied from the DC-DC converter 900, the charge pumping unit 711 boosts the DC voltage V1 of about 0V in a preselected (−) direction by the capacitors (not shown) and the diodes (not shown) connected in the reverse direction from the DC-DC converter 900, to supply the boosted voltage Vout of about −10V to the gate driver 400 through the discharging unit 712 and the offset voltage generator 713.

The boosted voltage Vout from the charge pumping unit 711 is charged in the capacitor C1 of the discharging unit 712 and the capacitor C2 of the offset voltage generator 713, and is supplied to the gate driver 400. At this time, the diode D11 of the offset voltage generator 713 maintains a turned-off state.

Next, an operation of the gate-off voltage generator 710 will be described when the power supply voltage is cut off from the LCD, for example by a user operation.

When the power supply voltage is cut off, the electric charges in the capacitor C1 of the discharging unit 712 are discharged through the resistor R1, and a voltage at an output terminal of the discharging unit 712, i.e., the A11 point, is gradually increased to a ground voltage of about 0V. A discharge time of the gate-off voltage Voff is defined based on an RC time constant calculated by a resistance of the resistor R1 and a capacitance of the capacitor C1.

Both terminals of the diode D11 maintain a voltage difference (hereinafter called an “offset voltage”) by a threshold voltage of about 0.7 V, by the operating of the capacitor C2 of the offset voltage generator 713. The offset voltage is added to the voltage at an output terminal A12 of the offset voltage generator 713. Therefore, the output voltage Voff of the offset voltage generator 713 is larger than the voltage at the output terminal A11 of the discharging unit 712. That is, the output voltage Voff is defined by the voltage at the output terminal A11 and the offset voltage and applied to the gate driver 400.

As described above, when the power supply voltage is cut off, an equivalent circuit diagram of the gate-off voltage generator 710, a switching element Q connected to a pixel electrode 191, a gate driver 400, and the data driver 500, are as shown in FIG. 4.

Referring to FIG. 4, the gate driver 400 is in a turned-on state, and the data driver 500 is grounded. The resistor R11 is a wiring resistor of a gate line, and the resistor R12 is a wiring resistor of a data line.

The gate-off voltage Voff (hereinafter called a “control voltage”) of about +0.7 V is applied to a control terminal G of the switching element Q through the gate driver 400 and resistor R11. Accordingly, a voltage Vgd between a control terminal G and an output terminal D of the switching element Q is defined and a current Ids corresponding to the voltage Vgd starts to flow from the output terminal D to the input terminal S of the switching element Q. A voltage at the point P1, i.e., a pixel electrode voltage, is discharged to the data driver 500 through the switching element Q. At this time, since the control voltage is larger than the voltage (about 0V) at the output terminal A11 of the discharging unit 712, the amount of the current I_{ds} become higher than in a case where the voltage of the output terminal A11 is about 0 V. The higher current I_{ds} accelerates the discharge speed of the pixel electrode voltage.

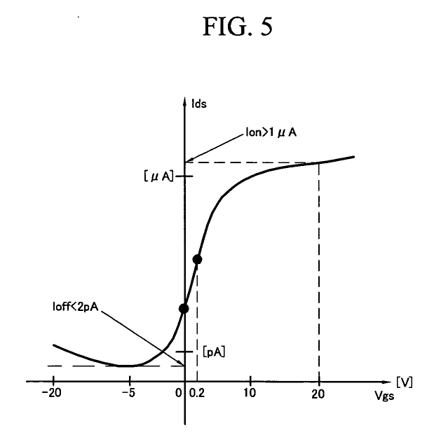

A variation of the current I_{ds} with respect to the voltage Vgd will be described with reference to FIG. 5.

FIG. 5 is a graph showing a current flowing between an output terminal and an input terminal of a switching element with respect to a voltage applied between a control terminal and the output terminal of the switching element of an a-Si thin film transistor.

Referring to FIG. 5, the amount of the current Ids increases as the voltage Vgs increases in a voltage range of about −5 V to +20 V. Therefore, when the control voltage of about +0.2 V rather than about 0 V is applied to the control terminal G of the switching element Q the amount of the current I_{ds} increases, thereby shortening the discharge time of the pixel electrode voltage.

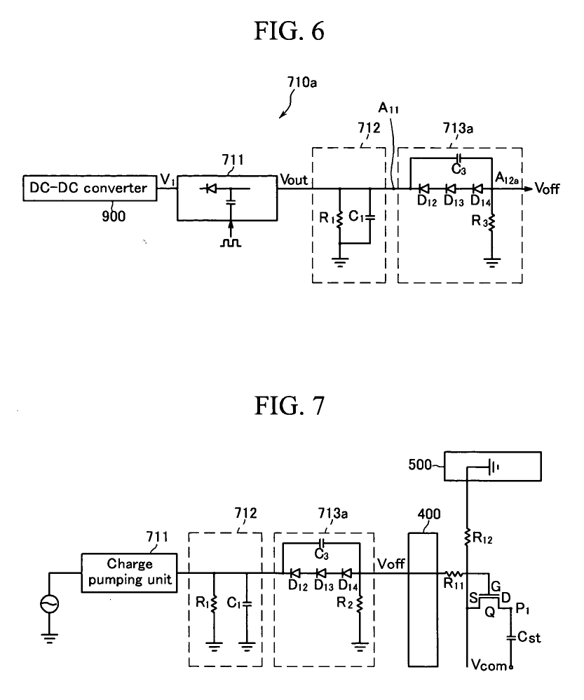

Now, a gate-off voltage generator according to a second embodiment of the present invention will be described with reference to FIGS. 6 and 7.

FIG. 6 is a circuit diagram of a gate-off voltage generator according to a second embodiment of the present invention, and FIG. 7 is an equivalent circuit diagram of the gate-off voltage generator shown in FIG. 6. A gate driver and a data driver are connected to the switching element of a pixel, and the power supply voltage is cut off from the LCD.

Referring to FIG. 6, a gate-off voltage generator 710a according to a second embodiment of the present invention has a structure equal to that of the gate-off voltage generator 710 shown in FIG. 3 except the offset voltage generator 713a. Therefore, the elements performing the same operations are indicated as the same reference numerals shown in FIG. 3, and the detailed description thereof is omitted.

As compared with the offset voltage generator 713 shown in FIG. 3, the offset voltage generator 713a differs in the number of diodes D12-D14 from that of the offset voltage generator 713. That is, the offset voltage generator 713 has one diode D11, but the offset voltage generator 713a as three diodes D12-D14 connected in series.

When the LCD is normally operated by supplying a power supply voltage thereto, the operation of the gate-off voltage generator 710a is similar to that of the gate-off voltage generator 710 shown in FIG. 3. That is, the charge pumping unit 711 boosts the DC voltage V1 in a preselected (−) direction with capacitors (not shown) and diodes (not shown) to generate a boosted voltage Vout of about −10 V. After charging the capacitors C1 and C3 of the discharging unit 712 and the offset voltage generator 713a, respectively, the boosted voltage Vout is supplied to the gate driver 400 as a gate-off voltage Voff.

When the power supply to the LCD is cut off, the electric charges in the capacitor Cl of the discharging unit 712 are discharged through the resistor R1. As a result, the voltage at an output terminal A11 of the discharging unit 712 is gradually discharged until it reaches a ground voltage of about 0 V.

However, a voltage at an output terminal A12a of the offset voltage generator 713a is about +2.1 V (+0.7 V×3) to be applied to the gate driver 400. That is, the voltage at the output terminal A12 is larger because the threshold voltages of the diodes D12-D14 become higher with each diode.

As shown in FIG. 7, when the power supply voltage is cut off, the gate driver 400 is in a turned-on state and the data driver 500 is grounded. Therefore, a voltage (hereinafter called a “control voltage”) applied to a control terminal G of the switching element Q has the offset voltage of about 2.1 V generated by the diodes D12-D14 and the capacitor C3 and a gate-off voltage that is substantially equal to the ground voltage. By applying the control voltage, a voltage Vgd between the control terminal G and an output terminal D of the switching element Q is increased. Thus, a leakage current I_{ds} flows between the output terminal D and an input terminal S of the switching element Q, of which amount is proportional to a magnitude of the control voltage to be increased. As a result, a discharge time of a pixel electrode voltage is shortened by the offset voltage generator 713a.

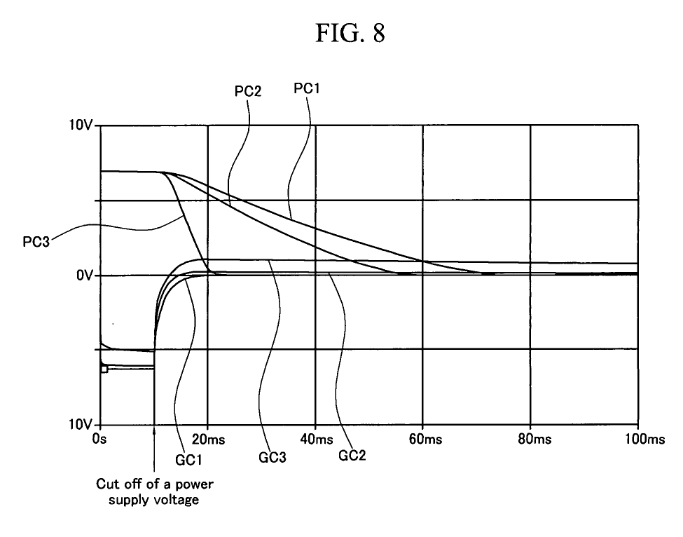

Referring to FIG. 8, variations of the control voltage applied to the control terminal G of the switching element Q and the pixel electrode voltage at the point P1 with and without implementing the gate-off voltage generators 713 and 713a will be described.

FIG. 8 is a graph showing variations of pixel electrode voltages with respect to control voltages when a power supply voltage is cut off from the LCD. In FIG. 8, GC1 and PC1 are curves illustrating variations of the control voltage and the pixel electrode voltage applied to the switching element according to a prior art, respectively, GC2 and PC2 are curves illustrating variations of the control voltage and the pixel electrode voltage applied to the switching element according to the first embodiment of the present invention, respectively, and GC3 and PC3 are curves illustrating variations of the control voltage and the pixel electrode voltage applied to the switching element according to the second embodiment of the present invention, respectively,.

Referring to FIG. 8, the respective curves GC1-GC3 indicate variation of the control voltage applied to the control terminal G of the switching element Q and the curves PC1-PC3 indicate variation of the pixel electrode voltage, that is, a voltage variation at the point P1.

As shown in FIG. 8, after the power supply voltage is cut off, the discharge time of the respective pixel electrode voltages shown in the curves PC1, PC2, and PC3 become shorter as the control voltage (about 0V, about 0.2V, and about 1.2V) becomes larger. More specifically, the discharge time (about 60 ms) of the pixel electrode voltage shown in the curve PC2 according to the first embodiment of the present invention shortens by about 10 ms and the discharge time (about 20 ms) of the pixel electrode voltage shown in the curve PC3 according to the second embodiment of the present invention shortens by about 50 ms, compared to the discharge time (about 75 ms) of the pixel electrode voltage shown in the curve PC1 according to the prior art. The difference between the gate-off voltage Voff applied to the gate driver 400 and the control voltage applied to the control terminal G of the switching element Q is caused by a voltage drop due to the wiring resistor R11 and so on.

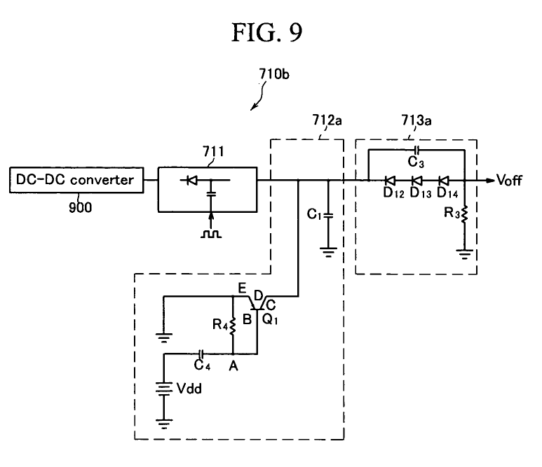

A gate-off voltage generator 710b according to a third embodiment of the present invention will be described with reference to FIG. 9.

FIG. 9 is a circuit diagram of a gate-off voltage generator according to a third embodiment of the present invention.

Referring to FIG. 9, a gate-off voltage generator 710b according to a third embodiment of the present invention is the same as the gate-off voltage generator 710a shown in FIG. 6 except for a discharging unit 712a. The elements performing the same operations as in the embodiment of FIG. 6 are indicated with the same reference numerals as in FIG. 6, and their detailed descriptions will not be repeated.

Referring to FIG. 9, the discharging unit 712a includes a capacitor C1 that is located between an output terminal of a charge pumping unit 711 and a ground, a transistor Q1, a resistor R4 connected between a base terminal B of the transistor Q1 and the ground, and a capacitor C4 connected between the base terminal B of the transistor Q1 and a power supply voltage Vdd. The collector terminal C of the transistor Q1 is connected to the output terminal of the charge pumping unit 711, and the emitter E terminal is connected to ground. In the embodiment shown, the transistor Q1 is a pnp-type transistor.

The power supply voltage Vdd may be supplied from the DC-DC converter 900, or it may be supplied from another device.

An operation of the discharging unit 712a will be described below.

When the LCD is operated normally by supplying the power supply voltage Vdd thereto, the discharging unit 712a is supplied with the power supply voltage Vdd. At this time, electric potential of the base terminal B of the transistor Q1 is higher than that of the emitter terminal E, and the switching element Q1 is turned off. Because the switching element Q1 is turned off, a discharge path for electric charges in the capacitor Cl of the discharging unit 712a is opened and the gate-off voltage Voff from the charge pumping unit 711 is applied to the gate driver 400 through an offset voltage generator 713a.

However, when the power supply voltage Vdd applied to the LCD is cut off, the magnitude of the power supply voltage Vdd is changed to about 0 V, equal to the ground voltage. Accordingly, electric charges in the capacitor C4 are discharged through the resistor R4, and the voltage at the base terminal B is decreased to the ground voltage. The discharge time is defined by an RC time constant based on the resistance of the resistor R4 and the capacitance of the capacitor C4. Until the discharging of the capacitor C4 through the resistor R4 is finished, the electric potential of the base terminal B of the transistor Q1 is lower than that of the emitter terminal E connected to the ground, so the transistor Q1 is turned on. Therefore, the electric charges in the capacitor C1 from the charge pumping unit 711 are discharged through the turned-on transistor Q1. The discharging of the gate-off voltage Voff is therefore performed without the delay by the RC time constant of the resistor R1 and the capacitor C1 shown in FIGS. 3 and 6, and the discharge time of the pixel electrode voltage through the switching element Q shown in FIG. 8 is shortened.

The discharging unit 712a is used in the gate-off voltage generator 710a shown in FIG. 6, but it may be adopted in the gate-off voltage generator 710 shown in FIG. 3.

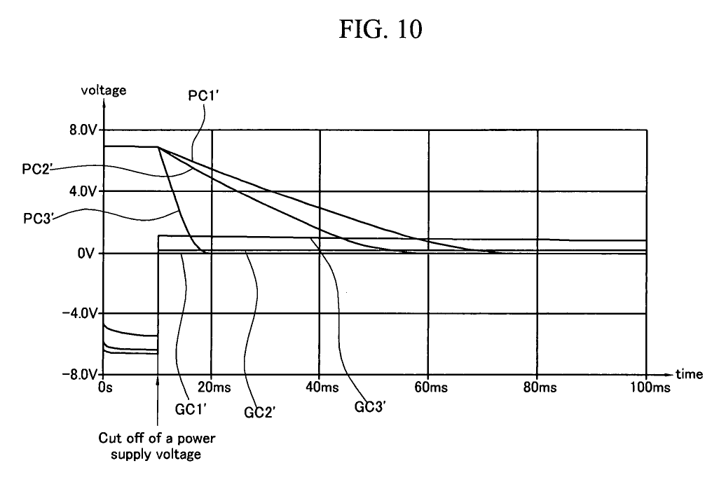

Variations of the control voltages shown in the curves GC1′-GC3′ applied to the control terminal G of the switching element Q and the pixel electrode voltages shown in the curves PC′-PC3′ will be described with reference to FIG. 10 as well as FIG. 8.

FIG. 10 is a graph showing variations of control voltages applied to a control terminal of a switching element connected to a pixel electrode and pixel electrode voltages when a discharging portion shown in FIG. 9 is adopted.

Referring to FIG. 8, when the gate-off voltage is changed to a target voltage of about 0 V, a delay occurs. The delay amount is determined by the RC time constant due to the resistor R1 and the capacitor C1.

However, referring to FIG. 10, since the delay due to the RC time constant does not occur, the control voltages shown in the curves GC1′-GC3′ are changed to the target voltage as the power supply voltage is cut off. GC1′ is a curve showing a variation of the control voltage when the power supply voltage is cut off after the discharging unit 712a shown in FIG. 9 is used in a gate-off voltage generator according to the prior art. GC2′ is a curve showing a variation of the control voltage when the power supply voltage is cut off after the discharging unit 712a shown in FIG. 9 is used in the gate-off voltage generator 710 shown in FIG. 3. GC3′ is a curve showing a variation of the control voltage of the gate-off generator 710b shown in FIG. 9 when the power supply voltage is cut off.

As described above, the discharge time of the control voltages shown in the curves GC1′-GC3′, and therefore the discharge time of the pixel electrode voltages shown in the curves PC1′-PC3′, shorten.

Comparing FIG. 10 with FIG. 8, the discharge time of the control voltages shown in the curves GC1′-GC3′ and the pixel electrode voltages shown in the curves PC1′-PC3 will be described in detail.

In FIG. 10, PC1′ is a curve showing a variation of the pixel electrode voltage when the power supply voltage is cut off after the discharging unit 712a shown in FIG. 9 is used in a gate-off voltage generator according to the prior art. PC2′ is a curve showing a variation of the pixel electrode voltage when the power supply voltage is cut off after the discharging unit 712a shown in FIG. 9 is used in the gate-off voltage generator 710 shown in FIG. 3, and PC3′ is a curve showing a variation of the pixel electrode voltage by the gate-off generator 710b shown in FIG. 9 when the supply voltage is cut off.

As shown in FIG. 10, the discharge time (about 70 ms) of the pixel electrode voltage of the curve PC1′ shortens by about 5 ms compared to the discharging time (about 75 ms) of the pixel electrode voltage of the curve PC1 shown in FIG. 8, the discharge time (about 55 ms) of the pixel electrode voltage of the curve PC2′ shortens by about 5 ms as compared with the discharging time (about 60 ms) of the pixel electrode voltage of the curve PC2 shown in FIG. 8, and the discharge time (about 18 ms) of the pixel electrode voltage of the curve PC3′ shortens by about 2 ms compared to the discharge time (about 20 ms) of the pixel electrode voltage of the curve PC2 shown in FIG. 8.

When the power supply voltage is cut off from an LCD, the magnitude of a control voltage applied to a switching element of a pixel is increased, thereby increasing a leakage current through the switching element to shorten the discharge time of the pixel electrode voltage. As a result, image deterioration due to the discharge delay of the pixel electrode voltage is increased.

When the gate-off voltage is discharged, the amount of current flowing between an input terminal and an output terminal of the switching element is not sufficiently high to discharge the gate-off voltage. This is at least partly because the magnitude of the voltage applied to the switching element is not large enough. The low current flowing between the input and the output terminal of the switching element lengthens the discharge time of the pixel electrode voltage.

The invention reduces the discharge time of the pixel electrode voltage by utilizing the fact that the discharge time of the pixel electrode is proportional to the discharge time of the control voltage. Shortening the discharge time of the control voltage also reduces the discharge time of the pixel electrode voltage, decreasing the image deterioration caused by the discharge delay of the pixel electrode voltage.

While the present invention has been described in detail with reference to the preferred embodiments, it is to be understood that the invention is not limited to the disclosed embodiments, but, on the contrary, is intended to cover various modifications and equivalent arrangements included within the spirit and scope of the appended claims.

What is claimed is:

1. A driving apparatus of a display device including a plurality of switching elements and a plurality of pixel electrodes connected to the switching elements, the apparatus comprising:
a gate-off voltage generator for generating a gate-off voltage; and
a gate driver for outputting the gate-off voltage from the gate-off voltage generator to the switching elements,
wherein the gate-off voltage generator increases the gate-off voltage to a predetermined voltage when a power supply voltage applied to the display device is cut off.

2. The apparatus of claim 1, wherein the gate-off voltage generator comprises:
a charge pumping unit for increasing an input voltage in a preselected direction by a predetermined magnitude to generate the gate-off voltage; and
an offset voltage generator for generating an offset voltage and adding the offset voltage to the discharge gate-off voltage to apply it to the switching element when the gate-off voltage from the charge pumping unit is discharged.

3. The apparatus of claim 2, wherein the gate-off voltage generator comprises:
at least one diode unit connected in a reverse direction between an output terminal of the charge pumping unit and the gate driver; and
a capacitor connected in parallel with the diode unit.

4. The apparatus of claim 3, wherein the offset voltage is controlled by the diode unit.

5. The apparatus of claim 4, wherein the diode unit has three diodes connected in series.

6. The apparatus of claim 2, wherein the gate-off voltage generator further comprises a discharging unit for providing a discharge path for the gate-off voltage.

7. The apparatus of claim 6, wherein the discharging unit comprises a resistor and a capacitor connected in parallel with the charge pumping unit.

8. The apparatus of claim 6, wherein the discharging unit comprises:
a first capacitor connected in parallel to the charge pumping unit;
a transistor having a collector terminal connected to the charge pumping unit and an emitter terminal grounded;
a resistor connected to the emitter terminal and a base terminal of the transistor; and
a second capacitor connected to the resistor; and
a supply voltage connected to the second capacitor.

9. The apparatus of claim 8, wherein the transistor is a pnp-type transistor.

10. The apparatus of claim 6, wherein the power supply voltage is received from an external device, and a magnitude of the power supply voltage is changed to the ground voltage when the power supply voltage is cut off.

11. The apparatus of claim 1, wherein the predetermined voltage is ground voltage.

12. A display device comprising:
a plurality of switching elements;
a plurality of pixel electrodes;
a plurality of gate lines connected to the switching elements and transmitting a gate-off voltage to the switching elements;
a gate-off voltage generator for generating the gate-off voltage; and
a gate driver for outputting the gate-off voltage from the gate-off voltage generator to the switching elements,
wherein the gate-off voltage generator increases the gate-off voltage to a predetermined voltage when a power supply voltage applied to the display device is cut off.

13. The apparatus of claim 12, wherein the gate-off voltage generator comprises:
a charge pumping unit for increasing an input voltage from the outside in a preselected direction by a predetermine magnitude to generate the gate-off voltage; and
an offset voltage generator for generating an offset voltage and adding the offset voltage to the discharge gate-off voltage to apply it to the switching element when the gate-off voltage from the charge pumping unit is discharged.

14. The apparatus of claim 13, wherein the gate-off voltage generator comprises:
at least one diode unit connected in a reverse direction between an output terminal of the charge pumping unit and the gate driver; and
a capacitor connected in parallel to the diode unit.

15. The apparatus of claim 14, wherein the diode unit comprises three diodes connected in series.

16. The apparatus of claim 13, wherein the gate-off voltage generator further comprises a discharging unit for supplying a discharge path for the gate-off voltage.

17. The apparatus of claim 16, wherein the discharging unit comprises a resistor and a capacitor connected in parallel with the charge pumping unit.

18. The apparatus of claim 15, wherein the discharging unit comprises:
a first capacitor connected in parallel with the charge pumping unit;
a transistor having a collector terminal connected to the charge pumping unit and an emitter terminal grounded;
a resistor connected to the emitter terminal and a base terminal of the transistor; and
a second capacitor connected to the resistor; and
a supply voltage connected to the second capacitor.

19. The apparatus of claim 18, wherein the transistor is a pnp-type of junction transistor.

20. The apparatus of claim 18, wherein the power supply voltage is received from an external device, and a magnitude of the power supply voltage is changed to the ground voltage when the power supply voltage is cut off.

21. The apparatus of claim 12, wherein the predetermine voltage is ground voltage.
